(19) United States
(12) Patent Application Publication
(10) Pub. No.: US 2025/0261517 A1
(43) Pub. Date: Aug. 14, 2025

(54) Display Panel and Method for Manufacturing the Same, and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Jiali Wang, Beijing (CN); Chienpang Huang, Beijing (CN); Wei Tang, Beijing (CN); Changbo Liu, Beijing (CN); Yanqiang Wang, Beijing (CN); Ling Shi, Beijing (CN); Weifeng Zhou, Beijing (CN); Haijun Qiu, Beijing (CN)

(21) Appl. No.: 18/992,335

(22) PCT Filed: Mar. 13, 2024
(86) PCT No.: PCT/CN2024/081535

§ 371 Date: Jan. 8, 2025

(30) Foreign Application Priority Data
Apr. 26, 2023 (CN) 202310466502.2

(51) Int. Cl. H10K 59/122; H10K 59/12; H10K 59/131; H10K 59/40; H10K 59/80

(52) U.S. Cl. CPC H10K 59/122; H10K 59/1201; H10K 59/131; H10K 59/40; H10K 59/8792; H10K 59/873

(57) ABSTRACT

A display panel includes a substrate, a pixel defining layer, a first electrode layer and a black matrix. The pixel defining layer is disposed on the substrate, and is provided with a plurality of first pixel openings and a plurality of first photosensitive openings. The first electrode layer is disposed on a side of the pixel defining layer away from the substrate. The black matrix is disposed on a side of the first electrode layer away from the substrate, and is provided with a plurality of second pixel openings and a plurality of second photosensitive openings. An orthogonal projection of at least one first pixel opening on the substrate is located within an orthographic projection of a second pixel opening on the substrate. An orthogonal projection of at least one second photosensitive opening on the substrate is located within an orthographic projection of a first photosensitive opening on the substrate.

### CROSS-REFERENCE TO RELATED APPLICATIONS

This application is the United States national phase of International Patent Application No. PCT/CN2024/081535, filed Mar. 13, 2024, and claims priority to Chinese Patent Application No. 202310466502.2, filed Apr. 26, 2023, the disclosures of which are hereby incorporated by reference in their entireties.

### BACKGROUND OF THE INVENTION

### Field of the Invention

The present disclosure relates to the field of display technologies, and in particular, to a display panel and a method for manufacturing the same, and a display apparatus.

### Description of Related Art

With rapid development of display technologies, display apparatuses have gradually come throughout people's lives. Organic light-emitting diodes (OLEDs) are widely used in smart products such as mobile phones, televisions and notebook computers due to advantages of self-luminescence, low power consumption, wide viewing angle, fast response speed, high contrast and flexible display.

### SUMMARY OF THE INVENTION

In an aspect, a display panel is provided. The display panel includes a substrate, a pixel defining layer, a first electrode layer and a black matrix. The pixel defining layer is disposed on the substrate. The pixel defining layer is provided therein with a plurality of first pixel openings and a plurality of first photosensitive openings. The first electrode layer is disposed on a side of the pixel defining layer away from the substrate. The black matrix is disposed on a side of the first electrode layer away from the substrate. The black matrix is provided therein with a plurality of second pixel openings and a plurality of second photosensitive openings. An orthogonal projection of at least one first pixel opening on the substrate is located within an orthogonal projection of a second pixel opening on the substrate; and an orthogonal projection of at least one second photosensitive opening on the substrate is located within an orthogonal projection of a first photosensitive opening on the substrate.

In some embodiments, a distance between an edge of the orthogonal projection of the first pixel opening on the substrate and an edge of the orthogonal projection of the corresponding second pixel opening on the substrate is in a range of 2 μm to 6 μm, inclusive; and/or a distance between an edge of the orthogonal projection of the first photosensitive opening on the substrate and an edge of the orthogonal projection of the corresponding second photosensitive opening on the substrate is in a range of 1.1 μm to 2 μm, inclusive.

In some embodiments, the display panel further includes a second electrode layer. The second electrode layer is disposed between the pixel defining layer and the substrate. The second electrode layer includes a plurality of second electrodes. An orthogonal projection of a first pixel opening on the substrate is located within an orthographic projection of a second electrode on the substrate; and an orthogonal projection of a second photosensitive opening on the substrate is located between orthographic projections of the plurality of second electrodes on the substrate.

In some embodiments, the display panel further includes a driving circuit layer. The driving circuit layer is disposed between the pixel defining layer and the substrate. An orthographic projection of the driving circuit layer on the substrate encloses a plurality of light-transmitting regions; and an orthogonal projection of a second photosensitive opening on the substrate substantially coincides with a light-transmitting region or is located within a light-transmitting region.

In some embodiments, the driving circuit layer includes a plurality of pixel circuits, a plurality of first signal line groups and a plurality of second signal line groups. The plurality of pixel circuits are arranged in a plurality of rows and a plurality of columns, a row of pixel circuits is divided into a plurality of pixel circuit groups, and a pixel circuit group includes two adjacent pixel circuits. Two pixel circuits in a same pixel circuit group are substantially symmetrical about a first axis, the first axis extends in a first direction, and the first direction is a column direction in which the plurality of pixel circuits are arranged.

Each first signal line group includes a plurality of first signal lines, and the plurality of first signal lines extend substantially in the first direction and are connected to two pixel circuits in the pixel circuit group. Each second signal line group includes a plurality of second signal lines, and the plurality of second signal lines extend substantially in a second direction and are each connected to a row of pixel circuits. The second direction is a row direction in which the plurality of pixel circuits are arranged. The light-transmitting region is located between two adjacent first signal lines belonging to different first signal line groups, and between two adjacent second signal lines belonging to a same second signal line group.

In some embodiments, the plurality of first signal lines in the first signal line group includes at least one power signal line and two data lines. The at least one power signal line is connected to at least one column of pixel circuits. The two data lines are each connected to a column of pixel circuits. The two data lines are located on opposite sides of the at least one power signal line. The light-transmitting region is located between two adjacent data lines belonging to different first signal line groups.

In some embodiments, the data lines each include first straight line segments and first bent segments that are alternately connected. In the two adjacent data lines belonging to different first signal line groups, two first bent segments are bent toward directions away from each other. The light-transmitting region is located between the two first bent segments.

In some embodiments, the plurality of second signal lines in the second signal line group include a first scanning signal line, a second scanning signal line, an enable signal line, a first initialization signal line, a second initialization signal line and a reset signal line arranged in sequence in the first direction. The light-transmitting region is located between the first scanning signal line and the second scanning signal line.

In some embodiments, the first scanning signal line includes second straight line segments and second bent segments that are alternately connected, and the second scanning signal line includes third straight line segments and third bent segments that are alternately connected. In the first scanning signal line and the second scanning signal line that are adjacent, a second bent segment and a third bent segment are bent toward directions away from each other. The light-transmitting region is located between the second bent segment and the third bent segment.

In some embodiments, the plurality of first pixel openings include a plurality of red pixel openings, a plurality of blue pixel openings and a plurality of green pixel openings. The plurality of red pixel openings and the plurality of blue pixel openings are arranged in an array of multiple rows and multiple columns, each row includes multiple red pixel openings and multiple blue pixel openings that are arranged alternately in a second direction, and each column includes multiple red pixel openings and multiple blue pixel openings that are arranged alternately in a first direction.

The plurality of green pixel openings are arranged in an array of multiple rows and multiple columns, each row includes multiple green pixel openings arranged in the second direction, and each column includes multiple green pixel openings arranged in the first direction. In the first direction, a green pixel opening is located between a red pixel opening and a blue pixel opening that are adjacent; and in the second direction, a green pixel opening is located between a red pixel opening and a blue pixel opening that are adjacent.

In some embodiments, in the first direction, a first photosensitive opening is located between two adjacent green pixel openings; and in the second direction, a first photosensitive opening is located between the red pixel opening and the blue pixel opening that are adjacent.

In some embodiments, the display panel further includes a touch layer. The touch layer includes a plurality of touch lines, and orthographic projections of the plurality of touch lines on the substrate are staggered from orthogonal projections of the second pixel openings and the second photosensitive openings on the substrate.

In some embodiments, the display panel has a display area. The display area includes a main display region and a photosensitive region, and the first photosensitive openings and the second photosensitive openings are located in the photosensitive region. In the photosensitive region, the plurality of touch lines are arranged crosswise to constitute a first mesh structure, and the first mesh structure includes a plurality of first grid rows and a plurality of second grid rows. A first grid row includes a plurality of first grids arranged in a second direction, and vertexes of two adjacent first grids are connected. A second grid row includes a plurality of second grids, a plurality of third grids, a plurality of fourth grids and a plurality of fifth grids arranged in the second direction.

A first grid is provided with a first pixel opening therein; a second grid is provided with a first photosensitive opening therein; a third grid is provided with a first pixel opening therein; a fourth grid is provided with a first pixel opening and two first photosensitive openings therein; and a fifth grid is provided with two first pixel openings and a first photosensitive opening therein.

In some embodiments, the first grid is substantially in a hexagonal shape; the second grid is substantially in a rectangular shape; and the third grid is substantially in a hexagonal shape. The fourth grid includes a first sub-grid and two second sub-grids. In a second direction, the two second sub-grids are disposed on opposite sides of the first sub-grid and communicated to the first sub-grid. The first sub-grid is substantially in a hexagonal shape, and the second sub-grids are each substantially in a rectangular shape. The fifth grid includes a third sub-grid and two fourth sub-grids. In the second direction, the two fourth sub-grids are disposed on opposite sides of the third sub-grid and communicated to the third sub-grid. The third sub-grid is substantially in a rectangular shape, and the fourth sub-grids are each in a hexagonal shape.

In some embodiments, the plurality of first pixel openings include a plurality of red pixel openings, a plurality of blue pixel openings and a plurality of green pixel openings. An orthogonal projection of a green pixel opening on the substrate is within an orthogonal projection of the first grid on the substrate. An orthogonal projection of a red pixel opening on the substrate is located in an orthogonal projection of any of the second grid, the third grid, the fourth grid and the fifth grid on the substrate; and an orthogonal projection of a blue pixel opening on the substrate is located in an orthogonal projection of any of the second grid, the third grid, the fourth grid and the fifth grid on the substrate.

In some embodiments, the display panel has a display area, the display area includes a main display region and a photosensitive region, and the first photosensitive openings and the second photosensitive openings are located in the photosensitive region. In the main display region, the plurality of touch lines are arranged crosswise to constitute a second mesh structure. The second mesh structure includes a plurality of sixth grids, the plurality of sixth grids are arranged in multiple rows and multiple columns, each row includes multiple sixth grids arranged in a second direction, and each column includes multiple sixth grids arranged in a first direction. Sixth grids of two adjacent rows are staggered, and a sixth grid is provided with a first pixel opening therein.

In some embodiments, the sixth grid is substantially in a rhombic shape.

In some embodiments, the display panel further includes an encapsulation layer. The encapsulation layer is disposed between the black matrix and the substrate. The encapsulation layer includes a plurality of encapsulation sub-films that are stacked, and any two adjacent encapsulation sub-films have different refractive indexes.

In some embodiments, the display panel further includes a color film. The color film is disposed on a side of the black matrix away from the substrate. The color film includes a plurality of filter patterns. The plurality of filter patterns and the plurality of second photosensitive openings are staggered, and the orthogonal projection of the second pixel opening on the substrate is located within an orthographic projection of a filter pattern on the substrate.

In some embodiments, an orthogonal projection of a first pixel opening on the substrate is located within the orthogonal projection of the second pixel opening on the substrate.

In another aspect, a method for manufacturing a display panel is provided. The method for manufacturing the display panel includes: forming a pixel defining layer on a substrate, the pixel defining layer being provided therein with a plurality of first pixel openings and a plurality of first photosensitive openings; forming a first electrode layer on a side of the pixel defining layer away from the substrate; and forming a black matrix on a side of the first electrode layer away from the substrate, wherein the black matrix is provided therein with a plurality of second pixel openings and a plurality of second photosensitive openings; an orthogonal projection of at least one first pixel opening on the substrate is located within an orthogonal projection of a second pixel opening on the substrate; and an orthogonal projection of at least one second photosensitive opening on the substrate is located within an orthogonal projection of a first photosensitive opening on the substrate.

In yet another aspect, a display apparatus is provided. The display apparatus includes the display panel according to any of the above embodiments and a photosensitive device. The display panel includes a light-exit side and a non-light-exit side that are opposite; and the photosensitive device is disposed on the non-light-exit side of the display panel.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display apparatus, in accordance with some embodiments;

FIG. 2 is a structural diagram of another display apparatus, in accordance with some embodiments;

FIG. 3 is a sectional view taken along a section line A-A′ in FIG. 1;

FIG. 4 is an exploded view of a display apparatus, in accordance with some embodiments;

FIG. 5A is a sectional view taken along a section line B-B′ in FIG. 4;

FIG. 5B is another sectional view taken along a section line B-B′ in FIG. 4;

FIG. 6 is a top view of a pixel defining layer of a display panel, in accordance with some embodiments;

FIG. 7 is a top view of a black matrix of a display panel, in accordance with some embodiments;

FIG. 8 is a structural diagram of stack of a pixel defining layer, a black matrix and spacers of a display panel, in accordance with some embodiments;

FIG. 9 is a partial enlarged view of a pixel defining layer of a display panel, in accordance with some embodiments;

FIG. 10 is a partial enlarged view of another pixel defining layer of a display panel, in accordance with some embodiments;

FIG. 11 is a partial enlarged view of a black matrix, a pixel defining layer, a second electrode layer and a driving circuit layer of a display panel, in accordance with some embodiments;

FIG. 12 is a partial enlarged view of a black matrix, a pixel defining layer and a driving circuit layer of a display panel, in accordance with some embodiments;

FIG. 13 is a partial enlarged view of a black matrix, a pixel defining layer and a driving circuit layer of another display panel, in accordance with some embodiments;

FIG. 14 is a partial enlarged view of a black matrix, a pixel defining layer and pixel circuits of a display panel, in accordance with some embodiments;

FIG. 15 is a partial enlarged view of two adjacent data lines belonging to different first signal line groups in FIG. 14;

FIG. 16 is a partial enlarged view of a first scanning signal line in FIG. 14;

FIG. 17 is a partial enlarged view of a second scanning signal line in FIG. 14;

FIG. 18 is a structural diagram of a touch layer in a photosensitive region, in accordance with some embodiments;

FIG. 19 is a partial enlarged view of a touch layer in a photosensitive region, in accordance with some embodiments;

FIG. 20 is a structural diagram of a touch layer in a main display region, in accordance with some embodiments;

FIG. 21 is a structural diagram of equivalent stacked film layers of an anti-reflection system formed by a first electrode layer, a light extraction layer and an encapsulation layer, in accordance with some embodiments;

FIG. 22 is a structural diagram of equivalent stacked film layers of an anti-reflection system formed by a first electrode layer and an encapsulation layer, in accordance with some embodiments;

FIG. 23 is a structural diagram of stack of a pixel defining layer, a black matrix, spacers and a color film of a display panel, in accordance with some embodiments; and

FIG. 24 is a flow chart of a method for manufacturing a display panel, in accordance with some embodiments.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. The term “connection” should be understood in a broad sense. For example, the “connection” may be a fixed connection, a detachable connection, or of an integrated structure; it may be a direct connection or an indirect connection by an intermediate medium. The term “coupled” indicates, for example, that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is optionally construed as “when” or “in a case where” or “in response to determining that” or “in response to detecting”, depending on the context. Similarly, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event]”, depending on the context.

The phrase “applicable to” or “configured to” as used herein indicates an open and inclusive expression, which does not exclude apparatuses that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

In consideration of the measurement in question and errors associated with the measurement of a particular quantity (i.e., limitations of the measurement system), the term “about”, “approximately” or “substantially” as used herein includes a stated value and mean within an acceptable range of deviation of a particular value, and the acceptable range of deviation is determined by a person of ordinary skill in the art. For example, the term “about” may mean within one or more standard deviations, or within ±30%, ±20%, ±10% or ±5% of the stated value.

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that, in a case where a layer or an element is referred to as being on another layer or a substrate, it may be that the layer or the element is directly on the another layer or the substrate, or there may be a middle layer between the layer or the element and the another layer or the substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in an apparatus, and are not intended to limit the scope of the exemplary embodiments.

In this specification, unless otherwise defined, all terms used herein (including technical terms and scientific terms) have the same meaning as commonly understood by those skilled in the art to which the present disclosure belongs. It will be further understood that unless explicitly defined here, terms (such as those defined in a general dictionary) should be interpreted as having a meaning consistent with their context in the relevant field and should not be interpreted as an ideal or overly formal meaning.

In the present disclosure, terms such as “lower”, “below”, “above”, “upper” and the like are used to explain a relational association of components shown in the drawings. The terms may be relative concepts, and are described based on directions shown in the drawings, or described based on an order in which the process steps are formed, but are not limited thereto.

The term “opposite” means that a first element and a second element may be directly or indirectly opposite. In a case where a third element is provided between the first element and the second element, the first element and the second element may be understood as being indirectly opposite to each other although still opposite to each other.

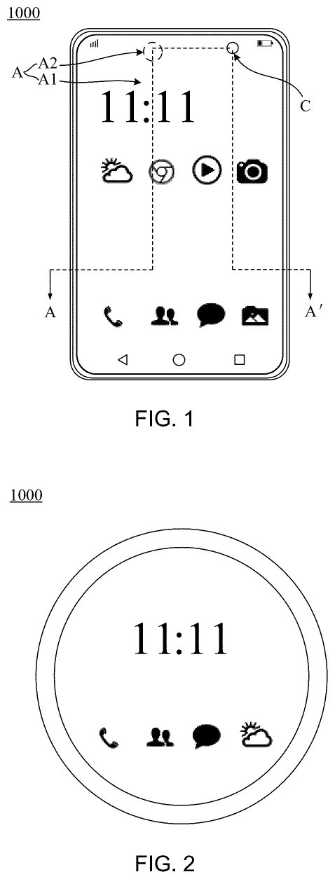

As shown in FIGS. 1 and 2, some embodiments of the present disclosure provide a display apparatus 1000. The display apparatus 1000 may be any apparatus that displays images whether in motion (e.g., a video) or stationary (e.g., a still image), and regardless of text or image.

For example, the display apparatus 1000 may be any product or component having a display function, such as a television, a notebook computer, a tablet computer, a mobile phone, a personal digital assistant (PDA), a navigator, a wearable device, a virtual reality (VR) device.

For example, as shown in FIG. 1, the display apparatus 1000 may be a portable display product; for example, the display apparatus 1000 is a mobile phone as shown in FIG. 1. As another example, referring to FIG. 2, the display apparatus 1000 may be a wearable device; for example, the display apparatus 1000 is a watch as shown in FIG. 2.

Some embodiments of the present disclosure will be schematically described below by taking an example in which the display apparatus 1000 is the mobile phone as shown in FIG. 1, but the implementations of the present disclosure are not limited thereto.

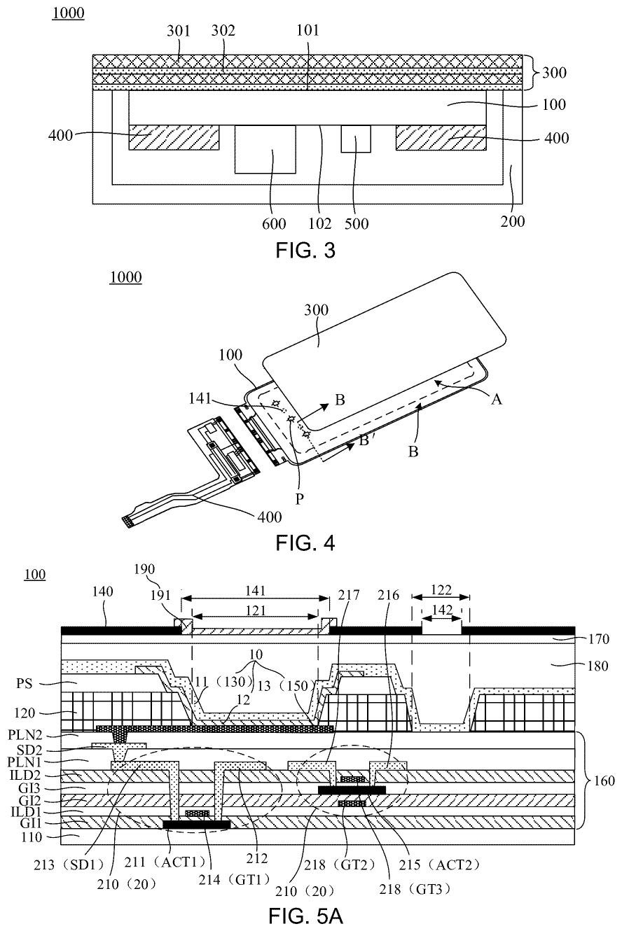

In some embodiments, referring to FIG. 3, the display apparatus 1000 includes a display panel 100.

The display panel 100 includes a light-exit side 101 and a non-light-exit side 102 that are opposite. The light-exit side refers to a side of the display panel 100 for display, that is, an upper side in FIG. 3.

For example, as shown in FIG. 3, the display apparatus 1000 may further include a housing 200, a cover plate 300, circuit boards 400, a photosensitive device 500, a camera 600 and other electronic components.

Referring to FIG. 3, the cover plate 300 may be a single-layer glass cover plate, or may include stack of multi-layer cover sub-plates 301. For example, as shown in FIG. 3, the cover plate 300 includes multi-layer cover sub-plates 301 that are arranged sequentially.

It will be noted that the above multi-layer cover sub-plates 301 may be bonded together by transparent adhesive layers 302, which is not specifically limited in the embodiments of the present disclosure. The light transmittance of the transparent adhesive layer 302 is greater than or equal to 90%.

As shown in FIG. 3, the housing 200 may have, for example, a U-shaped longitudinal section. The display panel 100 and the circuit boards 400 are disposed in the housing 200. The cover plate 300 is disposed at an opening of the housing 200. The circuit board 400 is disposed on a side of the display panel 100 away from the cover plate 300, and the circuit board 400 is connected to the display panel 100 to provide the display panel 100 with a required display signal.

As shown in FIGS. 1 and 3, the photosensitive device 500 and the camera 600 may be, for example, integrated below the display panel 100, that is, the photosensitive device 500 and the camera 600 are disposed on the non-light-exit side of the display panel 100, so as to increase a screen-to-body ratio. Here, the photosensitive device 500 includes at least one of an infrared sensor, a distance sensor, a fingerprint identification module and a brightness adjustment module.

The type of the display panel 100 varies, and may be selected according to actual needs.

For example, the display panel 100 is an organic light-emitting diode (OLED) display panel, or a quantum dot light-emitting diode (QLED) display panel, which is not specifically limited in the embodiments of the present disclosure.

Some embodiments of the present disclosure will be schematically described below by taking an example in which the display panel 100 is the OLED display panel.

In some embodiments, referring to FIG. 4, the display panel 100 has a display area A and a peripheral area B disposed on at least one side of the display area A. FIG. 4 illustrates an example in which the peripheral area B is disposed around the display area A.

Here, the display area A is an area for displaying images, and is configured to be provided with a plurality of sub-pixels P therein. The peripheral area B is an area without images displayed, and is configured to be provided therein with a display driver circuit, such as a gate driver circuit and a source driver circuit.

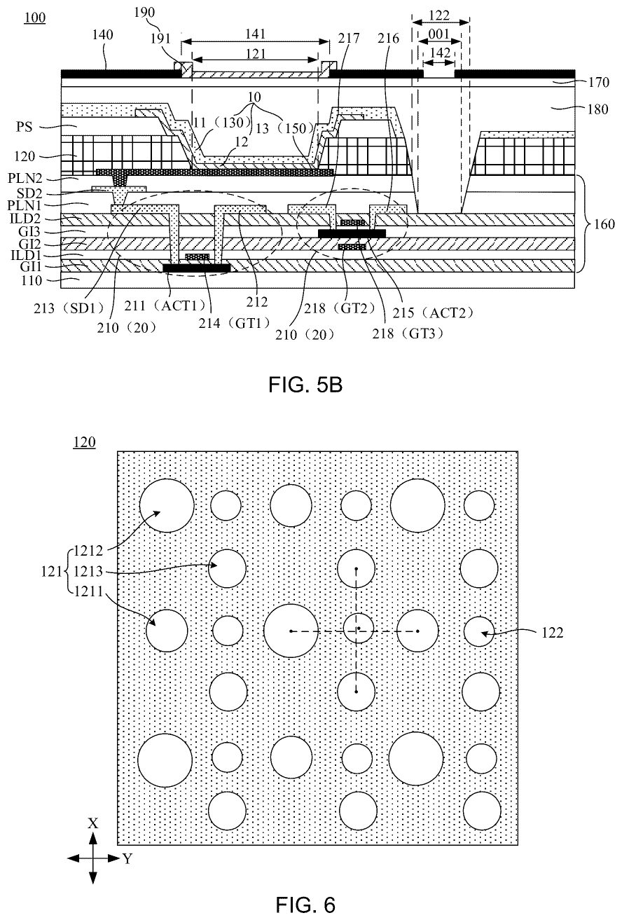

For example, as shown in FIGS. 4 and 5A, the display panel 100 includes a substrate 110 and a plurality of sub-pixels P disposed on a side of the substrate 110 and located in the display area A.

The type of the substrate 110 varies, and may be selected according to actual needs.

For example, the substrate 110 may be a rigid substrate. For example, the rigid substrate is a glass substrate or a polymethyl methacrylate (PMMA) substrate.

For example, the substrate 110 may be a flexible substrate. For example, the flexible substrate is a polyethylene terephthalate (PET) substrate, a polyethylene naphthalate two formic acid glycol ester (PEN) substrate, or a polyimide (PI) substrate.

Referring to FIG. 4, the plurality of sub-pixels P may include first sub-pixels for emitting light of first color, second sub-pixels for emitting light of second color and third sub-pixels for emitting light of third color.

It will be noted that the first color, the second color and the third color are three primary colors. For example, the first color is red, the second color is blue, and the third color is green.

Some embodiments of the present disclosure are schematically described below by taking an example in which the plurality of sub-pixels P include first sub-pixels for emitting red light, second sub-pixels for emitting blue light and third sub-pixels for emitting green light.

Referring to FIGS. 4 and 5A, each sub-pixel P includes a light-emitting device 10 and a pixel circuit 20. The pixel circuit 20 includes a plurality of thin film transistors 210.

As shown in FIG. 5A, the plurality of thin film transistors 210 include a low temperature polysilicon transistor and an oxide transistor. The low temperature polysilicon transistor includes a first semiconductor channel 211, a first source 212, a first drain 213 and a first gate 214. The first source 212 and the first drain 213 are both in contact with the first semiconductor channel 211. The oxide transistor includes a second semiconductor channel 215, a second source 216, a second drain 217 and second gates 218. The second source 216 and the second drain 217 are both in contact with the second semiconductor channel 215.

As shown in FIG. 5A, the light-emitting device 10 includes a first electrode 11, a light-emitting functional layer 12 and a second electrode 13. The second electrode 13 is electrically connected to the first source 212 or the first drain 213 of the low temperature polysilicon transistor. FIG. 5A illustrates an example in which the second electrode 13 is electrically connected to the first drain 213 of the low temperature polysilicon transistor.

It will be noted that the light-emitting functional layer 12 may include only a light-emitting layer; or may further include at least one of an electron transport layer (ETL), an electron injection layer (EIL), a hole transport layer (HTL) and a hole injection layer (HIL) in addition to the light-emitting layer.

In some embodiments, referring to FIG. 1, the display area A may include a main display region A1 and a photosensitive region A2, and the main display region A1 may, for example, surround the photosensitive region A2. Here, as shown in FIGS. 1 and 3, the photosensitive device 500 is located below the photosensitive region A2 of the display panel 100.

Referring to FIG. 1, the photosensitive region A2 may be located at the top of the display area A, that is, at a portion of the display area A relatively far away from a bonding portion of the display panel 100. Alternatively, the photosensitive region A2 may be located at other positions of the display area A. Limitations are not made specifically here in the embodiments of the present disclosure.

It will be noted that the photosensitive region A2 may be substantially in a shape of any of a circle, a polygon and an irregular figure. For example, as shown in FIG. 1, the photosensitive region A2 is substantially in a shape of a circle. An area of the photosensitive region A2 may be, for example, in a range of 7 mm² to 92 mm², inclusive. For example, the photosensitive region A2 is substantially in a shape of a circle, and a diameter of the circle is 3 mm.

In addition, referring to FIGS. 1 and 3, the display panel 100 may further have a camera area C, and a camera 600 is located below the camera area C of the display panel 100.

The display area A may, for example, surround the camera area C, and the camera area C may be located at the top of the display area A, that is, at a portion of the display area A relatively far away from the bonding portion of the display panel 100. Alternatively, the camera area C may be located at other positions of the display area A. Limitations are not made specifically here in the embodiments of the present disclosure.

In some related arts, there is a difference in reflectivity between the photosensitive region and the main display region, and thus an integrality of the display image may be destroyed, resulting in a poor display effect. In other related arts, the entire display area has a high reflectivity, and the external ambient light has a strong interference on the display image, resulting in a poor display effect.

In light of this, referring to FIG. 5A, the display panel 100 provided by some embodiments of the present disclosure further includes a pixel defining layer 120, a first electrode layer 130 and a black matrix 140.

In some examples, as shown in FIGS. 5A and 6, the pixel defining layer 120 is disposed on the substrate 110, that is, the pixel defining layer 120 is located on a side of the substrate 110 away from the photosensitive device 500 (referring to FIG. 3). Further, the pixel defining layer 120 is provided therein with a plurality of first pixel openings 121 and a plurality of first photosensitive openings 122.

Referring to FIGS. 1, 5A and 6, the plurality of first pixel openings 121 are arranged in the entire display area A, that is, the pixel defining layer 120 is provided therein with a plurality of first pixel openings 121 in both the main display region A1 and the photosensitive region A2. Here, a light-emitting device 10 is disposed in a first pixel opening 121.

For example, as shown in FIG. 6, the plurality of first pixel openings 121 include a plurality of red pixel openings 1211, a plurality of blue pixel openings 1212 and a plurality of green pixel openings 1213.

It will be noted that a light-emitting device 10 of the first sub-pixel is disposed in a red pixel opening 1211, a light-emitting device 10 of the second sub-pixel is disposed in a blue pixel opening 1212, and a light-emitting device 10 of the third sub-pixel is disposed in a green pixel opening 1213.

It will be understood that human eyes have different sensitivities to red light, green light and blue light, that is, the human eyes are more sensitive to green light than to red light, and the human eyes are more sensitive to red light than to blue light. Therefore, an area of the red pixel opening 1211 is smaller than an area of the blue pixel opening 1212, and larger than an area of the green pixel opening 1213.

On this basis, as shown in FIG. 6, the plurality of red pixel openings 1211 and the plurality of blue pixel openings 1212 may be, for example, arranged in an array of multiple rows and multiple columns. Each column includes multiple red pixel openings 1211 and multiple blue pixel openings 1212 that are arranged alternately in a first direction X. Each row includes multiple red pixel openings 1211 and multiple blue pixel openings 1212 that are arranged alternately in the second direction Y.

Moreover, the plurality of green pixel openings 1213 are arranged in an array of multiple rows and multiple columns. Each column includes multiple green pixel openings arranged in the first direction X. Each row includes multiple green pixel openings 1213 arranged in the second direction Y. A green pixel opening 1213 is located between red pixel openings 1211 and blue pixel openings 1212 of two adjacent rows and two adjacent columns. That is, in the first direction X, the green pixel opening 1213 is located between a red pixel opening 1211 and a blue pixel opening 1212 that are adjacent; and in the second direction Y, the green pixel opening 1213 is located between a red pixel opening 1211 and a blue pixel opening 1212 that are adjacent.

It will be noted that the first direction X may be, for example, a column direction in which the plurality of red pixel openings 1211 and the plurality of blue pixel openings 1212 are arranged, and the second direction Y may be, for example, a row direction in which the plurality of red pixel openings 1211 and the plurality of blue pixel openings 1212 are arranged. The first direction X is substantially perpendicular to the second direction Y.

In this case, the plurality of red pixel openings 1211, the plurality of blue pixel openings 1212 and the plurality of green pixel openings 1213 are arranged in the above manner, so that the display effect of the display panel 100 may be effectively improved, the display fineness may be improved, and an edge jagginess feeling and a display grainess feeling may be reduced.

Some embodiments of the present disclosure will be schematically described below by taking an example in which the plurality of red pixel openings 1211, the plurality of blue pixel openings 1212 and the plurality of green pixel openings 1213 are arranged in the above manner.

In some embodiments, as shown in FIG. 6, an orthogonal projection of each of the red pixel opening 1211, the blue pixel opening 1212 and the green pixel opening 1213 on the substrate 110 is substantially circular.

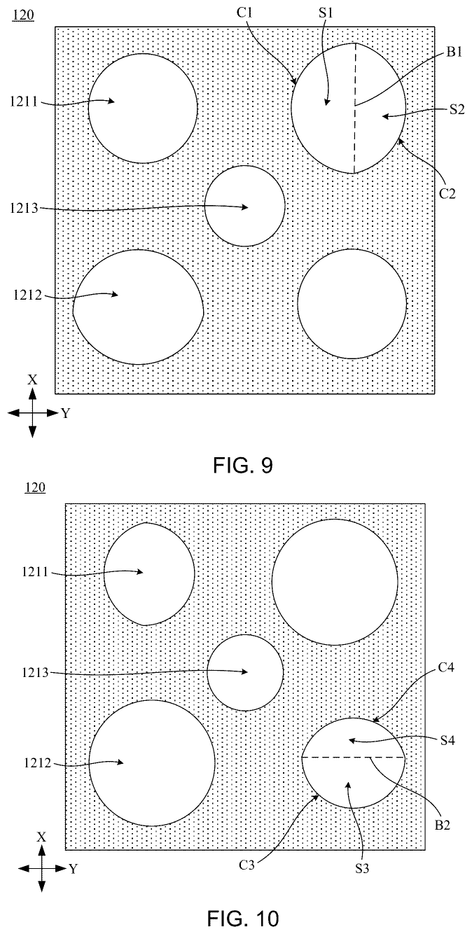

In some other embodiments, as shown in FIG. 9, an orthogonal projection of each of the red pixel opening 1211 and the green pixel opening 1213 on the substrate 110 is substantially circular.

An outer contour of the blue pixel opening 1212 includes a first curved edge C1 and a second curved edge C2. Both ends of the first curved edge C1 are connected to both ends of the second curved edge C2, and two connection points of the first curved edge C1 and the second curved edge C2 are a first connection point and a second connection point.

With continued reference to FIG. 9, a line for connecting the first connection point and the second connection point is a first line segment B1. The first line segment B1 has a length of a maximum dimension of the blue pixel opening 1212, and divides the blue pixel opening 1212 into a first sub-portion S1 including the first curved edge C1 and a second sub-portion S2 including the second curved edge C2. An area of the first sub-portion S1 is larger than an area of the second sub-portion S2.

In some other embodiments, as shown in FIG. 10, an orthogonal projection of each of the blue pixel opening 1212 and the green pixel opening 1213 on the substrate 110 is substantially circular.

An outer contour of the red pixel opening 1211 includes a third curved edge C3 and a fourth curved edge C4. Both ends of the third curved edge C3 are connected to both ends of the fourth curved edge C4, and two connection points of the third curved edge C3 and the fourth curved edge C4 are a third connection point and a fourth connection point.

With continued reference to FIG. 10, a line for connecting the third connection point and the fourth connection point is a second line segment B2. The second line segment B2 has a length of a maximum dimension of the red pixel opening 1211, and divides the red pixel opening 1211 into a third sub-portion S3 including the third curved edge C3 and a fourth sub-portion S4 including the fourth curved edge C4. An area of the third sub-portion S3 is larger than an area of the fourth sub-portion S4.

In this case, compared with the embodiments in which the outer contour of the blue pixel opening 1212 includes the first curved edge C1 and the second curved edge C2, in the embodiments in which the outer contour of the red pixel opening 1211 includes the third curved edge C3 and the fourth curved edge C4, an aperture ratio of the first pixel opening 121 (a total aperture ratio of the red pixel opening 1211, the blue pixel opening 1212 and the green pixel opening 1213) is relatively large.

It will be noted that the red pixel opening 1211, the blue pixel opening 1212 and the green pixel opening 1213 may also be in other shapes, which are not illustrated one by one in the embodiments of the present disclosure.

In some embodiments, referring to FIGS. 1 and 6, the plurality of first photosensitive openings 122 may be disposed in the entire display area A, that is, the pixel defining layer 120 is provided therein with a plurality of first photosensitive openings 122 in both the main display region A1 and the photosensitive region A2. Alternatively, the plurality of first photosensitive openings 122 may be only disposed in the photosensitive region A2, that is, the pixel defining layer 120 is provided therein with the plurality of first photosensitive openings 122 only in the photosensitive region A2. The external ambient light may pass through the first photosensitive opening 122 to be transmitted to the photosensitive device 500 (referring to FIG. 3) below the display panel 100 (referring to FIG. 3).

It will be understood that the first photosensitive opening 122 is disposed in a region between the plurality of first pixel openings 121.

For example, as shown in FIG. 6, in a case where the plurality of first pixel openings 121 include a plurality of red pixel openings 1211, a plurality of blue pixel openings 1212 and a plurality of green pixel openings 1213, in the first direction X, the first photosensitive opening 122 is located between two adjacent green pixel openings 1213; and in the second direction Y, the first photosensitive opening 122 is located between the red pixel opening 1211 and the blue pixel opening 1212 that are adjacent.

Here, in the first direction X, a line for connecting center points of two adjacent first photosensitive openings 122 and a line for connecting center points of two adjacent green pixel openings 1213 may be in the same straight line or may not be in the same straight line.

For example, as shown in FIG. 6, in the first direction X, the line for connecting the center points of two adjacent first photosensitive openings 122 and the line for connecting the center points of two adjacent green pixel openings 1213 may not be in the same straight line.

In addition, in the second direction Y, a line for connecting center points of two adjacent first photosensitive openings 122 and a line for connecting center points of a red pixel opening 1211 and a blue pixel opening 1212 that are adjacent may be in the same straight line or may not be in the same straight line.

For example, as shown in FIG. 6, in the second direction Y, the line for connecting the center points of two adjacent first photosensitive openings 122 and the line for connecting the center points of the red pixel opening 1211 and the blue pixel opening 1212 that are adjacent may not be in the same straight line.

In some examples, as shown in FIG. 5A, the first electrode layer 130 is disposed on a side of the pixel defining layer 120 away from the substrate 110. The first electrode layer 130 has a continuous whole layer structure. A portion of the first electrode layer 130 located in the first pixel opening 121 forms the first electrode 11 of the light-emitting device 10.

In some other examples, as shown in FIG. 5B, the first electrode layer 130 is disposed on a side of the pixel defining layer 120 away from the substrate 110. The first electrode layer 130 includes a patterned hollow structure. For example, the first electrode layer 130 has a mesh structure, and is hollowed out in a region corresponding to the first photosensitive opening 122 to reduce the reflectivity of the display panel 100.

It will be noted that a thickness of the first electrode layer 130 may be in a range of 60 Å to 200 Å, inclusive. For example, the thickness of the first electrode layer 130 is any of 60 Å, 70 Å, 80 Å, 90 Å, 100 Å, 110 Å, 120 Å, 124 Å, 130 Å, 140 Å and 150 Å.

In some example, as shown in FIG. 5A, the black matrix 140 is disposed on a side of the first electrode layer 130 away from the substrate 110. In addition, as shown in FIG. 7, the black matrix 140 is provided therein with a plurality of second pixel openings 141 and a plurality of second photosensitive openings 142.

It will be noted that the black matrix 140 is used to separate light emitted from different sub-pixels P, and has a function of reducing reflection of light after the external ambient light enters the display panel 100.

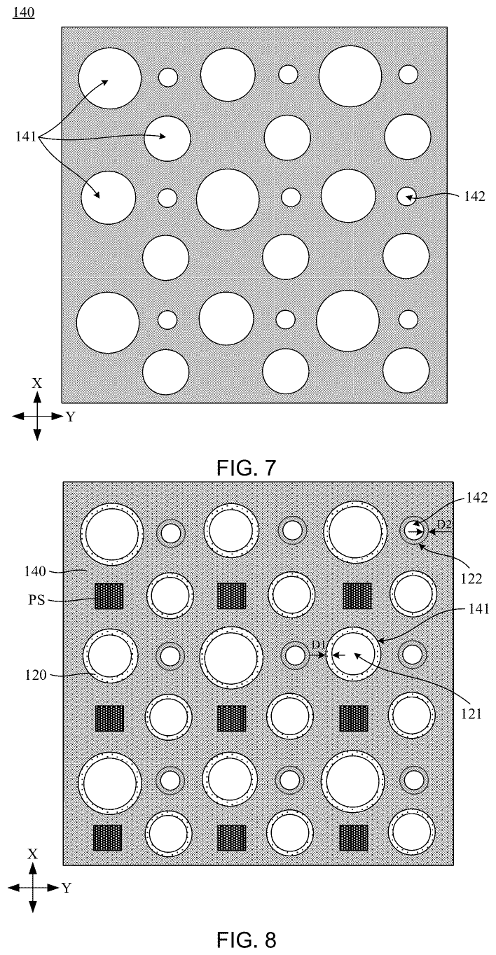

As shown in FIGS. 5A and 8, an orthogonal projection of a first pixel opening 121 on the substrate 110 is located within an orthogonal projection of a second pixel opening 141 on the substrate 110. That is, an area of the second pixel opening 141 is larger than an area of the first pixel opening 121. That is, each first pixel opening 121 in the pixel defining layer 120 defines a light-exit area of a light-emitting device 10.

It will be noted that the shape of the first pixel opening 121 and the shape of the second pixel opening 141 may be substantially the same, so as to control a distance between an edge of the orthogonal projection of the first pixel opening 121 on the substrate 110 and an edge of the orthogonal projection of the second pixel opening 141 on the substrate 110.

For example, a distance D1 between an edge of the orthogonal projection of the first pixel opening 121 on the substrate 110 and an edge of the orthogonal projection of the second pixel opening 141 on the substrate 110 is in a range of 2 μm to 6 μm, inclusive. In this way, it is conducive to design of a wide viewing angle of the display panel 100.

For example, the distance between the edge of the orthogonal projection of the first pixel opening 121 on the substrate 110 and the edge of the orthogonal projection of the second pixel opening 141 on the substrate 110 is any of 2 μm, 2.5 μm, 3 μm, 3.5 μm, 4 μm, 4.5 μm, 5.5 μm and 6 μm.

In addition, as shown in FIGS. 5A and 8, an orthogonal projection of a second photosensitive opening 142 on the substrate 110 is located within an orthogonal projection of a first photosensitive opening 122 on the substrate 110. That is, an area of the first photosensitive opening 122 is larger than an area of the second photosensitive opening 142. That is, each second photosensitive opening 142 in the black matrix 140 defines an area of a region, through which the external ambient light passes, of the display panel 100.

For example, a ratio of an area of the second pixel opening 141 to an area of the first pixel opening 121 is R1, and R1 is in a range of 1.1 to 1.5, inclusive. A ratio of an area of the first photosensitive opening 122 to an area of the second photosensitive opening 142 is R2, and R2 is in a range of 1.1 to 1.6, inclusive. R1 is less than or equal to R2. Thus, the design of the wide viewing angle of the display panel 100 may be ensured, and the area of the region, through which the external ambient light passes, of the display panel 100 may be limited.

In this case, in a case of the same areas of the external ambient light passing through the display panel 100, compared with each first photosensitive opening 122 in the pixel defining layer 120 limiting the area of the external ambient light passing through the display panel 100, each second photosensitive opening 142 in the black matrix 140 limiting the area of the external ambient light passing through the display panel 100 may reduce an area of the external ambient light passing through the second photosensitive opening 142 to the first electrode layer 130, and reduce an area of the external ambient light reflected by the first electrode layer 130.

In a case where the plurality of first photosensitive openings 122 are disposed in the entire display area A, each second photosensitive opening 142 in the black matrix 140 limits the area of external ambient light passing through the display panel 100 may reduce the reflectivity of the entire display panel 100 and improve the display effect.

In a case where the plurality of first photosensitive openings 122 are only disposed in the photosensitive region A2, each second photosensitive opening 142 in the black matrix 140 limits the area of external ambient light passing through the display panel 100 may reduce a difference in reflectivity between the photosensitive region A2 and the main display region A1 and improve the display effect.

It will be noted that the shape of the first photosensitive opening 122 and the shape of the second photosensitive opening 142 may be substantially the same, so as to control a distance between an edge of the orthogonal projection of the first photosensitive opening on the substrate 110 and an edge of the orthogonal projection of the second photosensitive opening on the substrate 110.

For example, a distance D2 between an edge of the orthogonal projection of the first photosensitive opening 122 on the substrate 110 and an edge of the orthogonal projection of the corresponding second photosensitive opening 142 on the substrate 110 is in a range of 1.1 μm to 2 μm, inclusive. In this way, it is beneficial for the pixel defining layer 120 to separate the light emitted from different sub-pixels P.

For example, the distance between the edge of the orthogonal projection of the first photosensitive opening 122 on the substrate 110 and the edge of the orthogonal projection of the corresponding second photosensitive opening 142 on the substrate 110 is any of 1.1 μm, 1.2 μm, 1.3 μm, 1.4 μm, 1.5 μm, 1.6 μm, 1.7 μm, 1.8 μm, 1.9 μm and 2 μm.

In some embodiments, as shown in FIG. 5A, the display panel 100 further includes a second electrode layer 150, and the second electrode layer 150 is disposed between the pixel defining layer 120 and the substrate 110.

In some examples, as shown in FIGS. 5A and 11, the second electrode layer 150 includes a plurality of second electrode 13. An orthogonal projection of a first pixel opening 121 on the substrate 110 is located within an orthographic projection of a second electrode 13 on the substrate 110. Moreover, an orthogonal projection of a second photosensitive opening 142 on the substrate 110 is located between orthographic projections of the plurality of second electrodes 13 on the substrate 110.

It will be noted that the second electrode 13 may be substantially in a shape of any of a polygon, a circle or an irregular figure. For example, the second electrode 13 may be in a shape of any of a rhombus, a regular hexagon, a regular octagon, a regular dodecagon and a circle. For example, the second electrode 13 is substantially in a shape of a regular octagon.

An orthogonal projection of a second pixel opening 141 on the substrate 110 may be located within an orthographic projection of a second electrode 13 on the substrate 110. Alternatively, an orthogonal projection of a second pixel opening 141 on the substrate 110 may be partially located within an orthographic projection of a second electrode 13 on the substrate 110, and partially located outside the orthographic projection of the second electrode 13 on the substrate 110. Limitations are not made specifically here in the embodiments of the present disclosure. FIG. 11 shows an example where the orthogonal projection of the second pixel opening 141 on the substrate 110 is located within the orthographic projection of the second electrode 13 on the substrate 110.

In addition, an orthogonal projection of a first photosensitive opening 122 on the substrate 110 may be located between orthographic projections of the plurality of second electrodes 13 on the substrate 110. Alternatively, an orthogonal projection of a first photosensitive opening 122 on the substrate 110 may be partially located between orthographic projections of the plurality of second electrodes 13 on the substrate 110, and partially located on the orthographic projections of the plurality of second electrodes 13 on the substrate 110. Limitations are not made specifically here in the embodiments of the present disclosure.

In this case, in a process that the external ambient light passes through the second photosensitive opening 142 to be transmitted to the photosensitive device 500 below the display panel 100, the external ambient light will not be affected by the second electrode 13, and the transmittance of the external ambient light at the second photosensitive opening 142 may be improved, thereby improving the photosensitivity of the display apparatus 1000 (referring to FIG. 1).

In some embodiments, as shown in FIG. 5A, the display panel 100 further includes a driving circuit layer 160, and the driving circuit layer 160 is disposed between the pixel defining layer 120 and the substrate 110. In a case where the display panel 100 includes the second electrode layer 150, the driving circuit layer 160 is located between the second electrode layer 150 and the substrate 110.

In some examples, as shown in FIGS. 5A and 11, an orthographic projection of the driving circuit layer 160 on the substrate 110 encloses a plurality of light-transmitting regions S. An orthogonal projection of a second photosensitive opening 142 on the substrate 110 substantially coincides with a light-transmitting region S. Alternatively, an orthogonal projection of a second photosensitive opening 142 on the substrate 110 is located within a light-transmitting region S.

In this case, referring to FIGS. 3, 8 and 11, in a process that the external ambient light passes through the second photosensitive opening 142 to be transmitted to the photosensitive device 500 below the display panel 100, the external ambient light will not be affected by the wiring in the driving circuit layer 160, and the transmittance of the external ambient light at the second photosensitive opening 142 may be improved, thereby improving the photosensitivity of the display apparatus 1000.

For example, referring to FIG. 11, an orthogonal projection of a second photosensitive opening 142 on the substrate 110 is located within a light-transmitting region S, and a minimum distance between an edge of the orthogonal projection of the second photosensitive opening 142 on the substrate 110 and an edge of the light-transmitting region S is greater than or equal to 1 μm.

For example, the distance between the edge of the orthogonal projection of the second photosensitive opening 142 on the substrate 110 and the edge of the light-transmitting region S is in a range of 1 μm to 2 μm, inclusive. For example, the distance between the edge of the orthogonal projection of the second photosensitive opening 142 on the substrate 110 and the edge of the light-transmitting region S is any of 1 μm, 1.2 μm, 1.5 μm, 1.7 μm, 1.8 μm, 1.9 μm and 2 μm.

In this case, the black matrix 140 (referring to FIG. 5A) may cover edges of the plurality of light-transmitting regions S enclosed by the orthographic projection of the driving circuit layer 160 on the substrate 110 to prevent light leakage at the second photosensitive opening 142 and make an area of the second photosensitive opening 142 designed to be relatively large.

In addition, an orthogonal projection of a first photosensitive opening 122 on the substrate 110 may also be located within a light-transmitting region S, and a minimum distance between an edge of the orthogonal projection of the first photosensitive opening 122 on the substrate 110 and an edge of the light-transmitting region S is greater than or equal to 1 μm.

For example, the distance between the edge of the orthogonal projection of the first photosensitive opening 122 on the substrate 110 and the edge of the light-transmitting region S is in a range of 1 μm to 2 μm, inclusive. For example, the distance between the edge of the orthogonal projection of the first photosensitive opening 122 on the substrate 110 and the edge of the light-transmitting region S is any of 1 μm, 1.2 μm, 1.5 μm, 1.7 μm, 1.8 μm, 1.9 μm and 2 μm.

In this case, the pixel defining layer 120 (referring to FIG. 5A) may also cover edges of the plurality of light-transmitting regions S enclosed by the orthographic projection of the driving circuit layer 160 on the substrate 110 to prevent light leakage at the first photosensitive opening 122 and make an area of the first photosensitive opening 122 designed to be relatively large.

In some embodiments, as shown in FIGS. 5A and 11 to 14, the driving circuit layer 160 includes a plurality of pixel circuits 20, a plurality of first signal line groups 30 and a plurality of second signal line groups 40.

As shown in FIG. 14, the plurality of pixel circuits 20 are arranged in a plurality of rows and a plurality of columns. A row of pixel circuits 20 is divided into a plurality of pixel circuit groups 220, and a pixel circuit group 220 includes two adjacent pixel circuits 20.

As shown in FIG. 14, the two pixel circuits 20 in the same pixel circuit group 220 are substantially symmetrical about a first axis M1, and the first axis M1 extends in the first direction X. The first direction X may also be a column direction in which the plurality of pixel circuits 20 are arranged.

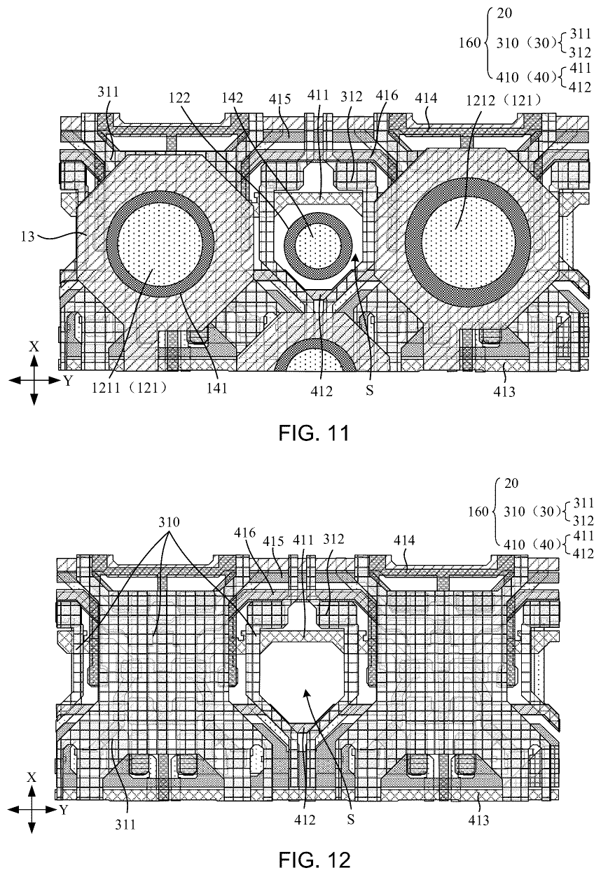

As shown in FIGS. 12, 13 and 14, each first signal line group 30 includes a plurality of first signal lines 310. The plurality of first signal lines 310 extend substantially in the first direction X and are connected to two pixel circuits 20 in the pixel circuit group 220. That is, a first signal line 310 is connected to a column of pixel circuits 20.

As shown in FIGS. 11 to 14, each second signal line group 40 includes a plurality of second signal lines 410. The plurality of second signal lines 410 extend substantially in the second direction Y and are each connected to a row of pixel circuits 20. The second direction Y may also be a row direction in which the plurality of pixel circuits 20 are arranged.

As shown in FIG. 11, the light-transmitting region S is located between two adjacent first signal lines 310 belonging to different first signal line groups 30, and between two adjacent second signal lines 410 belonging to the same second signal line group 40.

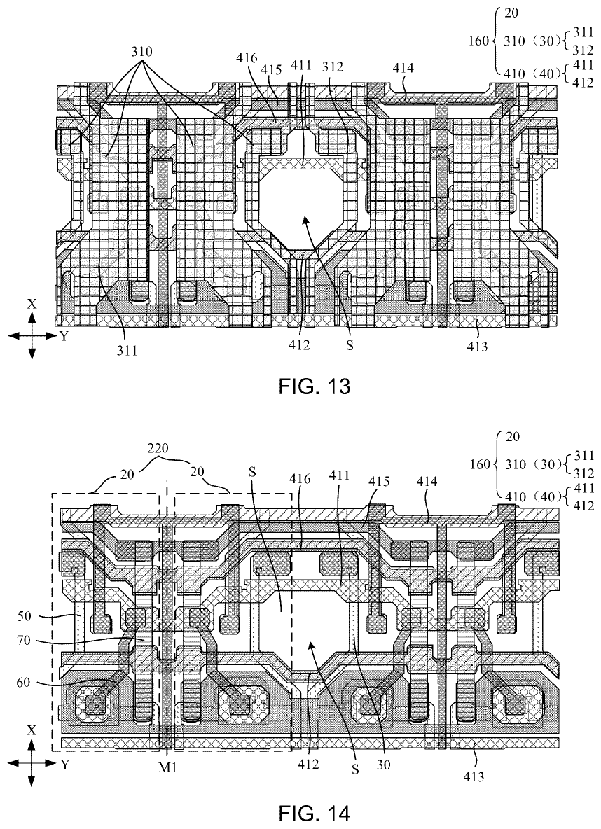

In some examples, as shown in FIGS. 12 and 13, the plurality of first signal lines 310 in the first signal line group 30 include at least one power signal line 311 and two data lines 312.

As shown in FIGS. 12, 13 and 14, at least one power signal line 311 is connected to at least one column of pixel circuits 20.

For example, as shown in FIGS. 12 and 14, the plurality of first signal lines 310 in the first signal line group 30 include one power signal line 311, and the power signal line 311 is connected to two pixel circuits 20 in the same pixel circuit group 220. In this case, the power signal line 311 may be substantially symmetrical about the first axis M1.

As another example, as shown in FIGS. 13 and 14, the plurality of first signal lines 310 in the first signal line group 30 include two power signal lines 311, and the two power signal lines 311 are respectively connected to two pixel circuits 20 in the same pixel circuit group 220. In this case, the two power signal lines 311 may be substantially symmetrical about the first axis M1.

As shown in FIGS. 12, 13 and 14, the two data lines 312 are each connected to a column of pixel circuits 20. That is, the two data lines 312 are respectively connected to two pixel circuits 20 in the same pixel circuit group 220. In this case, the two data lines 312 may also be substantially symmetrical about the first axis M1.

As shown in FIGS. 12 and 13, the two data lines 312 are located on opposite sides of all the power signal line(s) 311 in the first signal line group 30. In this case, there is no pixel circuit 20 between two adjacent data lines 312 belonging to different first signal line groups 30.

On this basis, as shown in FIGS. 12 and 13, the light-transmitting region S may be located, for example, between two adjacent data lines 312 belonging to different first signal line groups 30. In this way, an area of the light-transmitting region S may be designed to be relatively large, so that an area of the second photosensitive opening 142 may increase, thereby enhancing the transmittance of the photosensitive region A2 (referring to FIG. 1), and improving the photosensitivity of the display apparatus 1000 (referring to FIG. 1).

In addition, by changing the routing of the two adjacent data lines 312 belonging to different first signal line groups 30, an area of the light-transmitting region S that can be designed may further be increased.

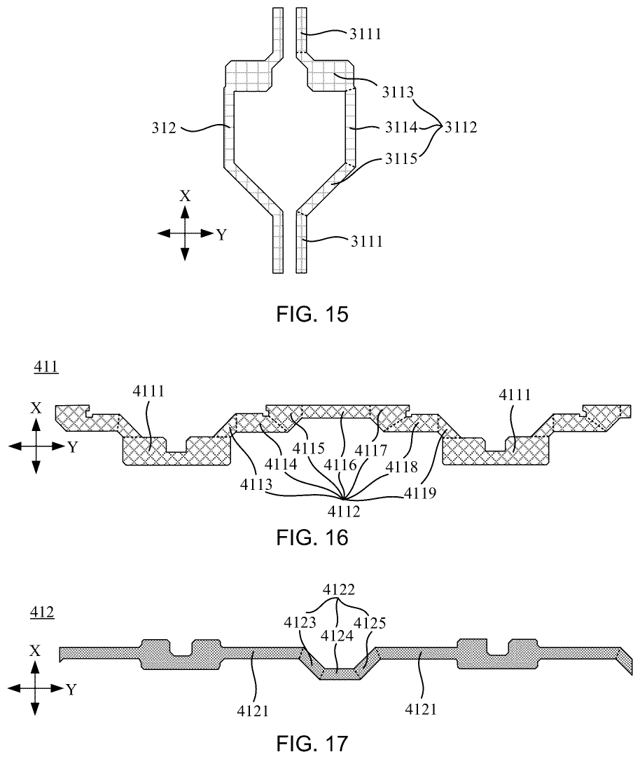

For example, referring to FIGS. 12 and 15, the data line 312 includes first straight line segments 3111 and first bent segments 3112 that are alternately connected. In the two adjacent data lines 312 belonging to different first signal line groups 30, two first bent segments 3112 are bent toward directions away from each other.

In this case, the light-transmitting region S may be located between the two first bent segments 3112. With such a provision, in the two adjacent data lines 312 belonging to different first signal line groups 30, the first bent segments 3112 are bent toward directions away from each other to forming avoidance, so that an area of the light-transmitting region S may be designed to be relatively large, and thus an area of the second photosensitive opening 142 may increase, thereby enhancing the transmittance of the photosensitive region A2 (referring to FIG. 1), and improving the photosensitivity of the display apparatus 1000 (referring to FIG. 1).

Referring to FIG. 15, the first bent segment 3112 may, for example, include a first data trace segment 3113, a second data trace segment 3114 and a third data trace segment 3115 that are connected in sequence.

As shown in FIGS. 12 and 15, the first data trace segment 3113 and the third data trace segment 3115 are respectively connected to first straight line segments 3111 on both sides of the first bent segment 3112. An extending direction of the second data trace segment 3114 is substantially the same as an extending direction of the first straight line segments 3111, and the second data trace segment 3114 is farther away from another adjacent data line 312 belonging to different first signal line groups 30 than the first straight line segment 3111.

In some examples, as shown in FIG. 14, the plurality of second signal lines 410 in the second signal line group 40 include a first scanning signal line 411, a second scanning signal line 412, an enable signal line 413, a first initialization signal line 414, a second initialization signal line 415 and a reset signal line 416 that are arranged sequentially in the first direction X.

It will be noted that, the first initialization signal line 414 may, for example, reset a second electrode 13 of a light-emitting device 10; and the second initialization signal line 415 may, for example, reset a control electrode of a driving transistor.

As shown in FIG. 14, the first scanning signal line 411, the second scanning signal line 412, the enable signal line 413, the first initialization signal line 414, the second initialization signal line 415 and the reset signal line 416 are arranged circularly in the first direction X.

As shown in FIGS. 11, 13 and 14, between two adjacent data lines 312 belonging to different first signal line groups 30, and in the plurality of second signal lines 410 arranged in the first direction X, the first scanning signal line 411 and the second scanning signal line 412 have a large spacing therebetween, and there is no obstruction by other conductive structures (e.g., the second electrode 13 and the pixel circuit 20).

On this basis, as shown in FIG. 14, the light-transmitting region S may be located, for example, between the first scanning signal line 411 and the second scanning signal line 412 that are adjacent. In this way, the area of the light-transmitting region S may be designed to be relatively large, so that the area of the second photosensitive opening 142 may increase, thereby enhancing the transmittance of the photosensitive region A2 (referring to FIG. 1), and improving the photosensitivity of the display apparatus 1000 (referring to FIG. 1).

In addition, by changing the routing of the first scanning signal line 411 and the second scanning signal line 412 that are adjacent, the area of the light-transmitting region S that can be designed may further be increased.

For example, referring to FIGS. 16 and 17, the first scanning signal line 411 includes second straight line segments 4111 and second bent segments 4112 that are alternately connected; and the second scanning signal line 412 includes third straight line segments 4121 and third bent segments 4122 that are alternately connected.

In combination with FIGS. 14, 16 and 17, in the first scanning signal line 411 and the second scanning signal line 412 that are adjacent, the second bent segment 4112 and the third bent segment 4122 are bent toward directions away from each other.

In this case, the light-transmitting region S is located between the second bent segment 4112 and the third bent segment 4122. With such a provision, in the first scanning signal line 411 and the second scanning signal line 412 that are adjacent, the second bent segment 4112 and the third bent segment 4122 are bent toward directions away from each other to forming avoidance, so that an area of the light-transmitting region S may be designed to be relatively large, and thus an area of the second photosensitive opening 142 may increase, thereby enhancing the transmittance of the photosensitive region A2 (referring to FIG. 1), and improving the photosensitivity of the display apparatus 1000 (referring to FIG. 1).

Referring to FIG. 16, the second bent segment 4112 may, for example, include a first scanning trace segment 4113, a second scanning trace segment 4114, a third scanning trace segment 4115, a fourth scanning trace segment 4116, a fifth scanning trace segment 4117, a sixth scanning trace segment 4118 and a seventh scanning trace segment 4119 that are connected in sequence.

As shown in FIGS. 14 and 16, the first scanning trace segment 4113 and the seventh scanning trace segment 4119 are respectively connected to second straight line segments 4111 on both sides of the second bent segment 4112. Extending directions of the second scanning trace segment 4114, the fourth scanning trace segment 4116 and the sixth scanning trace segment 4118 are substantially the same as an extending direction of the second straight line segments 4111, and the second scanning trace segment 4114 and the sixth scanning trace segment 4118 are farther away from the second scanning signal line 412 than the second straight line segments 4111. The fourth scanning trace segment 4116 is farther away from the adjacent second scanning signal line 412 than the second scanning trace segment 4114 and the sixth scanning trace segment 4118.

In addition, referring to FIG. 17, the third bent segment 4122 may include, for example, an eighth scanning trace segment 4123, a ninth scanning trace segment 4124 and a tenth scanning trace segment 4125.

As shown in FIGS. 14 and 17, the eighth scanning trace segment 4123 and the tenth scanning trace segment 4125 are respectively connected to third straight line segments 4121 on both sides of the third bent segment 4122. An extending direction of the ninth scanning trace segment 4124 is substantially the same as an extending direction of the third straight line segments 4121, and the ninth scanning trace segment 4124 is farther away from the adjacent first scanning signal line 411 than the third straight line segments 4121.

In some embodiments, as shown in FIGS. 5A and 14, the driving circuit layer 160 further includes first semiconductor patterns 50, transfer lines 60 and second semiconductor patterns 70.

On this basis, the first scanning signal line 411, the enable signal line 413, the first initialization signal line 414, the second initialization signal line 415 and the reset signal line 416 may, for example, overlap with the first semiconductor patterns 50 to form low temperature polysilicon transistors. The second scanning signal line 412 may, for example, overlap with the second semiconductor pattern 70 to form an oxide transistor.

In addition, a plurality of thin film transistors 210 of a plurality of pixel circuits 20 may be electrically connected by transfer lines 60 and conductive portions in the first semiconductor patterns 50 and/or the second semiconductor patterns 70.

On this basis, referring to FIG. 14, the light-transmitting region S may also be located, for example, between first semiconductor patterns 50 of the adjacent pixel circuits 20 belonging to different pixel circuit groups 220.

The driving circuit layer 160 mentioned above will be exemplarily introduced below in combination with the film layer structure of the display panel 100.

In some embodiments, as shown in FIG. 5A, in a direction perpendicular to the substrate 110 and away from the substrate 110, the display panel 100 includes a first semiconductor layer ACT1, a first gate conductive layer GT1, a second gate conductive layer GT2, a second semiconductor layer ACT2, a third gate conductive layer GT3, a first source-drain conductive layer SD1 and a second source-drain conductive layer SD2 sequentially.

It can be understood that referring to FIG. 5A, in the first semiconductor layer ACT1, the first gate conductive layer GT1, the second gate conductive layer GT2, the second semiconductor layer ACT2, the third gate conductive layer GT3, the first source-drain conductive layer SD1 and the second source-drain conductive layer SD2, every two adjacent layers are provided with an insulating layer therebetween, such as a first gate insulating layer GI1, a first interlayer insulating layer ILD1, a second gate insulating layer GI2, a third gate insulating layer GI3, a second interlayer insulating layer ILD2, a first planarization layer PLN1 and a second planarization layer PLN2, which are not specifically limited in the embodiments of the present disclosure.

Here, referring to FIG. 5B, the first planarization layer PLN1 and the second planarization layer PLN2 may also include a third photosensitive opening 001 extending through the first planarization layer PLN1 and the second planarization layer PLN2.

As shown in FIG. 5B, an orthogonal projection of the third photosensitive opening 001 on the substrate 110 is within an orthogonal projection of the first photosensitive opening 122 on the substrate 110, so that the first planarization layer PLN1 and the second planarization layer PLN2 provide support at the lower side of the pixel defining layer 120.

In addition, as shown in FIG. 5B, an orthogonal projection of the second photosensitive opening 142 on the substrate 110 is located within an orthogonal projection of the third photosensitive opening 001 on the substrate 110, so as to avoid adverse effects such as a decrease in transmittance caused by colors (e.g., light yellow) of the first planarization layer PLN1 and the second planarization layer PLN2 themselves, and color cast caused by reception of the external ambient light by the photosensitive device 500.

Of course, in some embodiments, the third photosensitive opening 001 may not be designed, and only the second photosensitive opening 142 and the first photosensitive opening 122 are included.

On this basis, in combination with FIGS. 5A and 14, the first semiconductor patterns 50 may be located in the first semiconductor layer ACT1. The first scanning signal lines 411 and the enable signal lines 413 may be located in the first gate conductive layer GT1. The second initialization signal lines 415 may be located in the second gate conductive layer GT2. The first initialization signal lines 414 may be located in the third gate conductive layer GT3. The second scanning signal line 412 may include two scanning signal sub-lines, where one scanning signal sub-line may be located in the second gate conductive layer GT2, and the other scanning signal sub-line may be located in the third gate conductive layer GT3. The reset signal line 416 may include two reset signal sub-lines, where one reset signal sub-line may be located in the second gate conductive layer GT2, and the other reset signal sub-line may be located in the third gate conductive layer GT3.

In some embodiments, referring to FIG. 5A, the display panel 100 further includes a touch layer 170. The touch layer 170 may be disposed on a side of the black matrix 140 away from the substrate 110, or may be disposed between the black matrix 140 and the pixel defining layer 120. For example, as shown in FIG. 5A, the touch layer 170 is disposed between the black matrix 140 and the pixel defining layer 120.

Here, the touch layer 170 may be directly formed on a side of an encapsulation layer 180 mentioned below away from the substrate 110 through a semiconductor process, that is, there is no other film layers disposed between the touch layer 170 and the encapsulation layer 180. With such a provision, the display apparatus 1000 (referring to FIG. 1) has a relatively small thickness, which is conducive to achieving lightness and thinness.

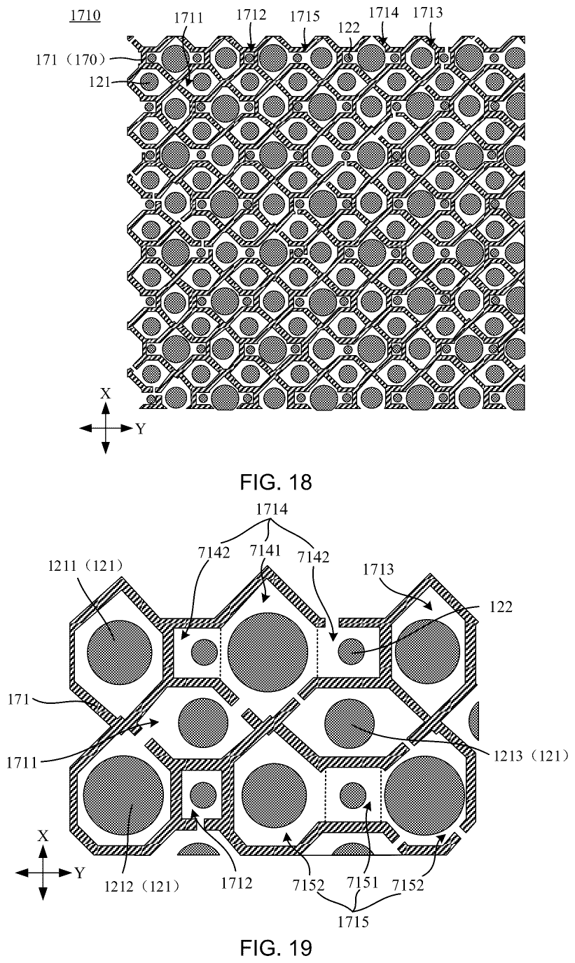

In some examples, as shown in FIG. 18, the touch layer 170 includes a plurality of touch lines 171, and orthographic projections of the plurality of touch lines 171 on the substrate 110 are staggered from orthogonal projections of the second pixel openings 141 on the substrate 110, so as to avoid blocking the light exit from the light-emitting device 10 caused by the touch lines 171 blocking part of the second pixel openings 141.

Moreover, the orthographic projections of the plurality of touch lines 171 on the substrate 110 are staggered from orthogonal projections of the second photosensitive openings 142 on the substrate 110, so as to avoid blocking the external ambient light received by the photosensitive device 500 through the second photosensitive openings 142 caused by the touch lines 171 blocking part of the second photosensitive openings 142.

The plurality of touch lines 171 form a plurality of driving electrodes and sensing electrodes that are insulated from each other, and a driving electrode and a sensing electrode may generate a capacitive node therebetween.

In this case, a pulsed or alternating voltage applied to the driving electrodes through a touch chip on the circuit board 400 (referring to FIG. 3) may induce charges on the sense electrode, and the amount of the induced charges is susceptible to external influences (e.g., touch or proximity of a finger). That is, when a finger touches or approaches the capacitive node, capacitance may change at the capacitive node, and the touch chip on the circuit board 400 (referring to FIG. 3) may measure the capacitance change through the sensing electrode, and determine a location where the finger touches or approaches by measuring the capacitance changes of the entire touch layer 170.

It will be noted that the driving electrodes and the sensing electrodes may be disposed in a same layer or in different layers.

For example, referring to FIGS. 1, 8 and 18, the first photosensitive opening 122 and the second photosensitive opening 142 are located in the photosensitive region A2. In this case, in the photosensitive region A2, the plurality of touch lines 171 are arranged crosswise to constitute a first mesh structure 1710. The first mesh structure 1710 includes a plurality of first grid rows and a plurality of second grid rows, and the plurality of second grid rows and the plurality of first grid rows are arranged alternately in the first direction X.

The first grid row includes a plurality of first grids 1711 arranged in the second direction Y, and vertexes of two adjacent first grids 1711 are connected. The second grid row includes a plurality of second grids 1712, a plurality of third grids 1713, a plurality of fourth grids 1714 and a plurality of fifth grids 1715 arranged in the second direction Y.

It will be noted that the arrangement of the second grids 1712, the third grids 1713, the fourth grids 1714 and the fifth grids 1715 is not unique, and is not described in detail in the embodiments of the present disclosure.

On this basis, as shown in FIG. 18, a first grid 1711 may be provided with a first pixel opening 121 therein. A second grid 1712 may be provided with a first photosensitive opening 122 therein. A third grid 1713 may be provided with a first pixel opening 121 therein. A fourth grid 1714 may be provided with a first pixel opening 121 and two first photosensitive openings 122 therein. A fifth grid 1715 may be provided with two first pixel openings 121 and a first photosensitive opening 122 therein.

It will be noted that part of edges of the first grids 1711, the second grids 1712, the third grids 1713, the fourth grids 1714 and the fifth grids 1715 may be disconnected, so that the driving electrodes and the sensing electrodes formed by the touch lines 171 are disconnected and insulated.

In this case, the plurality of touch lines 171 may be provided in the same layer and with the same material, that is, the plurality of driving electrodes and sensing electrodes that are insulated from each other may be provided in the same layer and with the same material. Moreover, the plurality of touch lines 171 are arranged crosswise to form the first mesh structure 1710, which is conducive to adapting to first pixel openings 121 of various shapes. Thus, it may facilitate the disconnection of driving electrodes and sensing electrodes to be insulation, and a structure is simple.

For example, as shown in FIGS. 18 and 19, the first grid 1711 is substantially in a hexagonal shape. The second grid 1712 is substantially in a rectangular shape. The third grid 1713 is substantially in a hexagonal shape.

In this case, the first grid 1711 may be provided therein with a first pixel opening 121, such as a green pixel opening 1213. The second grid 1712 may be provided therein with a first photosensitive opening 122. The third grid 1713 may be provided therein with a first pixel opening 121, such as a red pixel opening 1211 or a blue pixel opening 1212.

The fourth grid 1714 includes a first sub-grid 7141 and two second sub-grids 7142. In the second direction Y, the two second sub-grids 7142 are disposed on opposite sides of the first sub-grid 7141 and are communicated to the first sub-grid 7141. The first sub-grid 7141 is substantially in a hexagonal shape, and the second sub-grid 7142 is substantially in a rectangular shape.

In this case, the first sub-grid 7141 may be provided therein with a first pixel opening 121, such as a red pixel opening 1211 or a blue pixel opening 1212. The second sub-grid 7142 may be provided therein with a first photosensitive opening 122.

In addition, the fifth grid 1715 includes a third sub-grid 7151 and two fourth sub-grids 7152. In the second direction Y, the two fourth sub-grids 7152 are disposed on opposite sides of the third sub-grid 7151 and are communicated to the third sub-grid 7151. The third sub-grid 7151 is substantially in a rectangular shape, and the fourth sub-grid 7152 is substantially in a hexagonal shape.

In this case, the third sub-grid 7151 may be provided therein with a first photosensitive opening 122. The fourth sub-grid 7152 may be provided therein with a first pixel opening 121, such as a red pixel opening 1211 or a blue pixel opening 1212.

It can be seen from the above that in a case where the plurality of first pixel openings 121 include a plurality of red pixel openings 1211, a plurality of blue pixel openings 1212 and a plurality of green pixel openings 1213, an orthogonal projection of a green pixel opening 1213 on the substrate 110 is located within an orthogonal projection of the first grid 1711 on the substrate 110; an orthogonal projection of a red pixel opening 1211 on the substrate 110 is located in an orthogonal projection of any of the second grid 1712, the third grid 1713, the fourth grid 1714 and the fifth grid 1715 on the substrate 110; and an orthogonal projection of a blue pixel opening 1212 on the substrate 110 is located in an orthogonal projection of any of the second grid 1712, the third grid 1713, the fourth grid 1714 and the fifth grid 1715 on the substrate 110.

For example, referring to FIGS. 1 and 8, the first photosensitive opening 122 and the second photosensitive opening 142 are located in the photosensitive region A2. In this case, referring to FIGS. 1, 8 and 20, in the main display region A1, the plurality of touch lines 171 are arranged crosswise to constitute a second mesh structure 1720. The second mesh structure 1720 includes a plurality of sixth grids 1721, and the plurality of sixth grids 1721 are arranged in multiple rows and multiple columns. Each row includes multiple sixth grids 1721 arranged in the second direction Y, and each column includes multiple sixth grids 1721 arranged in the first direction X.

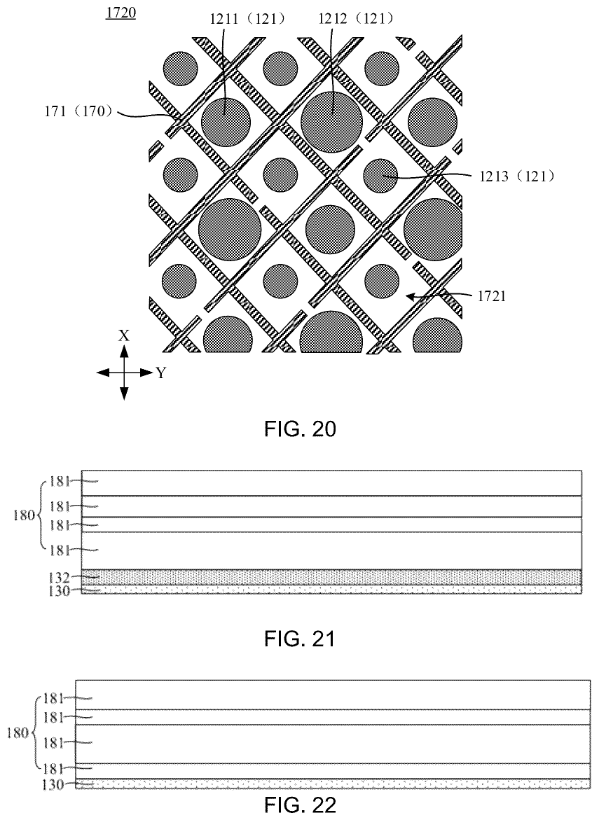

As shown in FIG. 20, the sixth grids 1721 of two adjacent rows are staggered, and a sixth grid 1721 is provided with a first pixel opening 121 therein. Here, the sixth grid 1721 is substantially in a shape of any of a rectangle, a rhombus, a regular hexagon, a regular octagon, and other polygons. For example, the sixth grid 1721 is substantially in a shape of a rhombus.

It will be noted that part of edges of the sixth grids 1721 may be disconnected, so that the driving electrodes and the sensing electrodes formed by the touch lines 171 are disconnected and insulated.

In this case, the plurality of touch lines 171 may be provided in the same layer and with the same material, that is, the plurality of driving electrodes and sensing electrodes that are insulated from each other may be provided in the same layer and with the same material. Moreover, the plurality of touch lines 171 are arranged crosswise to form the second mesh structure 1720, which is conducive to adapting to first pixel openings 121 of various shapes. Thus, it may facilitate the disconnection of driving electrodes and sensing electrodes to be insulation, and a structure is simple.

In some embodiments, referring to FIG. 5A, the display panel 100 further includes an encapsulation layer 180. The encapsulation layer 180 is disposed between the black matrix 140 and the pixel defining layer 120 to reduce the risk of corrosion of moisture and oxygen.

In this case, in a case where the display panel 100 further includes a touch layer 170, the touch layer 170 may be located between the black matrix 140 and the encapsulation layer 180.

In some examples, referring to FIGS. 5A and 21, the encapsulation layer 180 includes a plurality of encapsulation sub-films 181 that are stacked, and any two adjacent encapsulation sub-films 181 have different refractive indexes. Moreover, the encapsulation layer 180 is configured to reduce the reflectivity to the external ambient light.

The refractive index of the encapsulation sub-film 181 is in a range of 1.52 to 1.8, inclusive. For example, the refractive index of the encapsulation sub-film 181 is any of 1.52, 1.55, 1.6, 1.63, 1.68, 1.73, 1.75 and 1.8.

In addition, a thickness of the encapsulation sub-film 181 is in a range of 50 nm to 1000 nm, inclusive. For example, the thickness of the encapsulation sub-film 181 is any of 50 nm, 60 nm, 100 nm, 120 nm, 130 nm, 150 nm, 185 nm, 200 nm, 300 nm, 350 nm, 500 nm, 600 nm, 660 nm, 800 nm, 900 nm, 960 nm and 1000 nm.

Since the human eye perceives light with a wavelength of about 380 nm to 780 nm, and is more sensitive to light with a wavelength of about 550 nm, the reflectivity and transmittance of the display panel 100 are tested below using the light with a wavelength of 550 nm.

In addition, as the thickness of the first electrode layer 130 increases, the reflectivity to the light with a wavelength of about 380 nm and about 780 nm increases, and the transmittance decreases. In this case, the cooperation between the plurality of encapsulation sub-films 181 of the encapsulation layer 180 and the first electrode layer 130 may make the transmittance of the photosensitive region A2 of the display panel 100 greater than or equal to 0.6%, and a difference in reflectivity between the photosensitive region A2 and the main display region A1 less than or equal to 0.6%.

In some examples, as shown in FIG. 21, the display panel 100 further includes a light extraction layer 132, and the light extraction layer 132 is disposed between the first electrode layer 130 and the encapsulation layer 180 to protect the first electrode layer 130 and adjust light extraction, so as to improve the light extraction efficiency. The light extraction layer 132 may include a lithium fluoride layer.

For example, referring to FIG. 21, a thickness of the first electrode layer 130 is 110 Å. In this case, the transmittance of the first electrode layer 130 is approximately 60.82%, and the reflectivity thereof is approximately 24.66%.

On this basis, a thickness of the lithium fluoride layer is 60 nm. In this case, the encapsulation layer 180 includes four encapsulation sub-films 181. In a direction away from the first electrode layer 130 to the encapsulation layer 180, the refractive indexes of the four encapsulation sub-films 181 are 1.73, 1.63, 1.63 and 1.83 sequentially, and the thicknesses of the four encapsulation sub-films 181 are 960 nm, 120 nm, 185 nm and 350 nm sequentially.

In this case, for light with a wavelength of 550 nm, the difference in reflectivity between the photosensitive region A2 and the main display region A1 of the display panel 100 is less than or equal to 0.51%, and the transmittance of the photosensitive region A2 of the display panel 100 is greater than or equal to 0.6%.

As another example, referring to FIG. 21, a thickness of the first electrode layer 130 is 100 Å. In this case, the transmittance of the first electrode layer 130 is approximately 64.61%, and the reflectivity thereof is approximately 21.49%.

On this basis, a thickness of the lithium fluoride layer is 60 nm. In this case, the encapsulation layer 180 includes four encapsulation sub-films 181. In a direction away from the first electrode layer 130 to the encapsulation layer 180, the refractive indexes of the four encapsulation sub-films 181 are 1.73, 1.63, 1.63 and 1.83 sequentially, and the thicknesses of the four encapsulation sub-films 181 are 960 nm, 120 nm, 185 nm and 350 nm sequentially.

In this case, for light with a wavelength of 550 nm, the difference in reflectivity between the photosensitive region A2 and the main display region A1 of the display panel 100 is less than or equal to 0.49%, and the transmittance of the photosensitive region A2 of the display panel 100 is greater than or equal to 0.61%.

In some other examples, as shown in FIG. 22, there is no light extraction layer provided on the first electrode layer 130. In this case, the encapsulation layer 180 includes four encapsulation sub-films 181.

For example, referring to FIG. 22, a thickness of the first electrode layer 130 is 124 Å. In this case, the transmittance of the first electrode layer 130 is approximately 55.74%, and the reflectivity thereof is approximately 29.05%.

On this basis, in a direction away from the first electrode layer 130 to the encapsulation layer 180, the refractive indexes of the four encapsulation sub-films 181 are 1.52, 1.73, 1.63 and 1.83 sequentially, and the thicknesses of the four encapsulation sub-films 181 are 100 nm, 960 nm, 100 nm and 660 nm sequentially.

In this case, for light with a wavelength of 550 nm, the difference in reflectivity between the photosensitive region A2 and the main display region A1 of the display panel 100 is less than or equal to 0.6%, and the transmittance of the photosensitive region A2 of the display panel 100 is greater than or equal to 0.6%.

As another example, referring to FIG. 22, a thickness of the first electrode layer 130 is 110 Å. In this case, the transmittance of the first electrode layer 130 is approximately 64.61%, and the reflectivity thereof is approximately 21.49%.

On this basis, in a direction away from the first electrode layer 130 to the encapsulation layer 180, the refractive indexes of the four encapsulation sub-films 181 are 1.52, 1.73, 1.63 and 1.83 sequentially, and the thicknesses of the four encapsulation sub-films 181 are 50 nm, 960 nm, 130 nm and 660 nm sequentially.

In this case, for light with a wavelength of 550 nm, the difference in reflectivity between the photosensitive region A2 and the main display region A1 of the display panel 100 is less than or equal to 0.5%, and the transmittance of the photosensitive region A2 of the display panel 100 is greater than or equal to 0.6%.

As another example, referring to FIG. 22, a thickness of the first electrode layer 130 is 100 Å. In this case, the transmittance of the first electrode layer 130 is approximately 64.61%, and the reflectivity thereof is approximately 21.49%.

On this basis, in a direction away from the first electrode layer 130 to the encapsulation layer 180, the refractive indexes of the four encapsulation sub-films 181 are 1.52, 1.73, 1.63 and 1.83 sequentially, and the thicknesses of the four encapsulation sub-films 181 are 50 nm, 960 nm, 130 nm and 660 nm sequentially.

In this case, for light with a wavelength of 550 nm, the difference in reflectivity between the photosensitive region A2 and the main display region A1 of the display panel 100 is less than or equal to 0.48%, and the transmittance of the photosensitive region A2 of the display panel 100 is greater than or equal to 0.61%.

In some embodiments, referring to FIG. 5A, the display panel 100 further includes a color film 190, and the color film 190 is disposed on a side of the black matrix 140 away from the substrate 110.

It will be noted that the color film 190 can filter out light with most wavelength bands of the external ambient light, thereby reducing the reflection intensity of the external ambient light on the display panel 100.

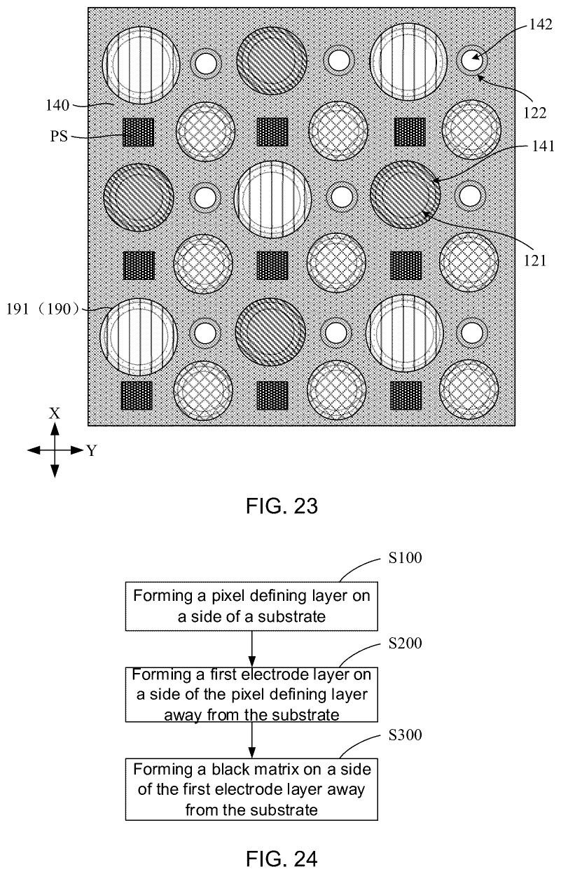

As shown in FIGS. 5A and 23, the color film 190 includes a plurality of filter patterns 191, and the plurality of filter patterns 191 and the plurality of second photosensitive openings 142 are arranged in a staggered manner.

It will be noted that the “staggered arrangement” here not only includes a case that orthographic projections of the filter patterns 191 on the substrate 110 has no overlap with orthogonal projections of the second photosensitive openings 142 on the substrate 110, but also includes a case that an orthographic projection of the filter pattern 191 on the substrate 110 is adjacent to an orthogonal projection of the second photosensitive opening 142 on the substrate 110, and parts of edges that are close to each other coincide.

For example, a distance between an edge of an orthographic projection of the filter pattern 191 on the substrate 110 and an edge of an orthogonal projection of the second photosensitive opening 142 on the substrate 110 is in a range of 0 μm to 1.8 μm, inclusive. For example, the distance between the edge of the orthographic projection of the filter pattern 191 on the substrate 110 and the edge of the orthogonal projection of the second photosensitive opening 142 on the substrate 110 is any of 0 μm, 0.4 μm, 0.8 μm, 0.9 μm, 1.4 μm, 1.6 μm and 1.8 μm.

In addition, as shown in FIGS. 5A and 23, an orthogonal projection of a second pixel opening 141 on the substrate 110 is located within an orthographic projection of a filter pattern 191 on the substrate 110.

A distance between an edge of an orthographic projection of the filter pattern 191 on the substrate 110 and an edge of an orthogonal projection of the second pixel opening 141 on the substrate 110 is greater than or equal to 4.5 μm, so that the filter pattern 191 and the black matrix 140 have relatively high adhesiveness, thereby reducing the risk of the filter pattern 191 falling off from the black matrix 140.

Here, referring to FIG. 23, the shape of the filter pattern 191 may be substantially the same as the shape of the second pixel opening 141, or may be different from the shape of the second pixel opening 141.

It will be noted that a material of the filter pattern 191 includes an organic material. For example, the material of the filter pattern 191 includes at least one of polymethyl methacrylate, general polymers of polystyrene, polymer derivatives with phenolic groups, acryloyl polymers, imide polymers, aryl ether polymers, amide polymers, fluorine polymers, paraxylene polymers or vinyl alcohol polymers.

In some embodiments, referring to FIGS. 5A and 8, the display panel 100 further includes spacers PS, and the spacers PS are disposed between the pixel defining layer 120 and the first electrode layer 130.

It will be noted that the spacer PS may be used to support a mask during the process, so that the mask and the pixel defining layer 120 have a uniform gap therebetween.

As shown in FIGS. 6 and 8, in a case where the plurality of first pixel openings 121 include a plurality of red pixel openings 1211, a plurality of blue pixel openings 1212 and a plurality of green pixel openings 1213, in the first direction X, the spacer PS is located between a red pixel opening 1211 and a blue pixel opening 1212 that are adjacent; and in the second direction Y, the spacer PS is located between two adjacent green pixel openings 1213, and thus is staggered from the first photosensitive openings 122.

Some embodiments of the present disclosure further provide a method for manufacturing a display panel 100. As shown in FIG. 24, the method includes steps S100 to S300.

In S100, referring to FIGS. 5A and 5B, a pixel defining layer 120 is formed on a side of the substrate 110.

In the above step, the pixel defining layer 120 is provided therein with a plurality of first pixel openings 121 and a plurality of first photosensitive openings 122.

In S200, referring to FIGS. 5A and 5B, a first electrode layer 130 is formed on a side of the pixel defining layer 120 away from the substrate 110.

In the above step, the structure of the first electrode layer 130 may refer to the above text, and the embodiments of the present disclosure are not described in detail here.

In S300, referring to FIGS. 5A and 5B, a black matrix 140 is formed on a side of the first electrode layer 130 away from the substrate 110.

In the above step, the black matrix 140 is provided therein with a plurality of second pixel openings 141 and a plurality of second photosensitive openings 142. An orthogonal projection of at least one first pixel opening 121 on the substrate 110 is located within an orthogonal projection of a second pixel opening 141 on the substrate 110; and an orthogonal projection of at least one second photosensitive opening 142 on the substrate 110 is located within an orthogonal projection of a first photosensitive opening 122 on the substrate 110.

Beneficial effects of the method for manufacturing the display panel 100 provided in the embodiments of the present disclosure are the same as beneficial effects of the display panel 100 provided in the above technical solutions, and details are not repeated here in the embodiments of the present disclosure.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display panel, comprising:
a substrate;
a pixel defining layer disposed on the substrate, wherein the pixel defining layer is provided therein with a plurality of first pixel openings and a plurality of first photosensitive openings;
a first electrode layer disposed on a side of the pixel defining layer away from the substrate; and
a black matrix disposed on a side of the first electrode layer away from the substrate, wherein the black matrix is provided therein with a plurality of second pixel openings and a plurality of second photosensitive openings; an orthogonal projection of at least one first pixel opening on the substrate is located within an orthogonal projection of a second pixel opening on the substrate; and an orthogonal projection of at least one second photosensitive opening on the substrate is located within an orthogonal projection of a first photosensitive opening on the substrate.

2. The display panel according to claim 1, wherein a distance between an edge of the orthogonal projection of the first pixel opening on the substrate and an edge of the orthogonal projection of the corresponding second pixel opening on the substrate is in a range of 2 μm to 6 μm, inclusive; and/or
a distance between an edge of the orthogonal projection of the first photosensitive opening on the substrate and an edge of the orthogonal projection of the corresponding second photosensitive opening on the substrate is in a range of 1.1 μm to 2 μm, inclusive.

3. The display panel according to claim 1, further comprising:
a second electrode layer disposed between the pixel defining layer and the substrate, wherein the second electrode layer includes a plurality of second electrodes, an orthogonal projection of a first pixel opening on the substrate is located within an orthographic projection of a second electrode on the substrate; and an orthogonal projection of a second photosensitive opening on the substrate is located between orthographic projections of the plurality of second electrodes on the substrate.

4. The display panel according to claim 1, further comprising:
a driving circuit layer disposed between the pixel defining layer and the substrate, wherein an orthographic projection of the driving circuit layer on the substrate encloses a plurality of light-transmitting regions; and an orthogonal projection of a second photosensitive opening on the substrate substantially coincides with a light-transmitting region or is located within a light-transmitting region.

5. The display panel according to claim 4, wherein the driving circuit layer includes:
a plurality of pixel circuits arranged in a plurality of rows and a plurality of columns, wherein a row of pixel circuits is divided into a plurality of pixel circuit groups, and a pixel circuit group includes two adjacent pixel circuits; two pixel circuits in a same pixel circuit group are substantially symmetrical about a first axis, the first axis extends in a first direction, and the first direction is a column direction in which the plurality of pixel circuits are arranged;
a plurality of first signal line groups, wherein each first signal line group includes a plurality of first signal lines, the plurality of first signal lines extend substantially in the first direction and are connected to two pixel circuits in the pixel circuit group; and
a plurality of second signal line groups, wherein each second signal line group includes a plurality of second signal lines, the plurality of second signal lines extend substantially in a second direction and are each connected to a row of pixel circuits; the second direction is a row direction in which the plurality of pixel circuits are arranged; wherein
the light-transmitting region is located between two adjacent first signal lines belonging to different first signal line groups, and between two adjacent second signal lines belonging to a same second signal line group.

6. The display panel according to claim 5, wherein the plurality of first signal lines in the first signal line group includes:
at least one power signal line connected to at least one column of pixel circuits; and
two data lines each connected to a column of pixel circuits, wherein the two data lines are located on opposite sides of the at least one power signal line; and the light-transmitting region is located between two adjacent data lines belonging to different first signal line groups.

7. The display panel according to claim 6, wherein the data lines each include first straight line segments and first bent segments that are alternately connected; in the two adjacent data lines belonging to different first signal line groups, two first bent segments are bent toward directions away from each other; and the light-transmitting region is located between the two first bent segments.

8. The display panel according to claim 5, wherein the plurality of second signal lines in the second signal line group include a first scanning signal line, a second scanning signal line, an enable signal line, a first initialization signal line, a second initialization signal line and a reset signal line arranged in sequence in the first direction; and the light-transmitting region is located between the first scanning signal line and the second scanning signal line.

9. The display panel according to claim 8, wherein the first scanning signal line includes second straight line segments and second bent segments that are alternately connected, and the second scanning signal line includes third straight line segments and third bent segments that are alternately connected; and
in the first scanning signal line and the second scanning signal line that are adjacent, a second bent segment and a third bent segment are bent toward directions away from each other; and the light-transmitting region is located between the second bent segment and the third bent segment.

10. The display panel according to claim 1, wherein the plurality of first pixel openings include a plurality of red pixel openings, a plurality of blue pixel openings and a plurality of green pixel openings;
the plurality of red pixel openings and the plurality of blue pixel openings are arranged in an array of multiple rows and multiple columns, each row includes multiple red pixel openings and multiple blue pixel openings that are arranged alternately in a second direction, and each column includes multiple red pixel openings and multiple blue pixel openings that are arranged alternately in a first direction; and
the plurality of green pixel openings are arranged in an array of multiple rows and multiple columns, each row includes multiple green pixel openings arranged in the second direction, and each column includes multiple green pixel openings arranged in the first direction;
in the first direction, a green pixel opening is located between a red pixel opening and a blue pixel opening that are adjacent; and in the second direction, a green pixel opening is located between a red pixel opening and a blue pixel opening that are adjacent.

11. The display panel according to claim 10, wherein in the first direction, a first photosensitive opening is located between two adjacent green pixel openings; and in the second direction, a first photosensitive opening is located between the red pixel opening and the blue pixel opening that are adjacent.

12. The display panel according to claim 1, further comprising:
a touch layer including a plurality of touch lines, wherein orthographic projections of the plurality of touch lines on the substrate are staggered from orthogonal projections of the second pixel openings and the second photosensitive openings on the substrate.

13. The display panel according to claim 12, wherein the display panel has a display area, the display area includes a main display region and a photosensitive region, and the first photosensitive openings and the second photosensitive openings are located in the photosensitive region;
in the photosensitive region, the plurality of touch lines are arranged crosswise to constitute a first mesh structure, and the first mesh structure includes:
a plurality of first grid rows, a first grid row including a plurality of first grids arranged in a second direction, and vertexes of two adjacent first grids are connected; and
a plurality of second grid rows each including a plurality of second grids, a plurality of third grids, a plurality of fourth grids and a plurality of fifth grids arranged in the second direction, wherein
a first grid is provided with a first pixel opening therein; a second grid is provided with a first photosensitive opening therein; a third grid is provided with a first pixel opening therein; a fourth grid is provided with a first pixel opening and two first photosensitive openings therein; and a fifth grid is provided with two first pixel openings and a first photosensitive opening therein.

14. The display panel according to claim 13, wherein the first grid is substantially in a hexagonal shape; the second grid is substantially in a rectangular shape; and the third grid is substantially in a hexagonal shape; the fourth grid includes a first sub-grid and two second sub-grids; in a second direction, the two second sub-grids are disposed on opposite sides of the first sub-grid and communicated to the first sub-grid; the first sub-grid is substantially in a hexagonal shape, and the second sub-grids are each substantially in a rectangular shape; and the fifth grid includes a third sub-grid and two fourth sub-grids; in the second direction, the two fourth sub-grids are disposed on opposite sides of the third sub-grid and communicated to the third sub-grid; the third sub-grid is substantially in a rectangular shape, and the fourth sub-grids are each in a hexagonal shape; and/or
the plurality of first pixel openings include a plurality of red pixel openings, a plurality of blue pixel openings and a plurality of green pixel openings; an orthogonal projection of a green pixel opening on the substrate is within an orthogonal projection of the first grid on the substrate; an orthogonal projection of a red pixel opening on the substrate is located in an orthogonal projection of any of the second grid, the third grid, the fourth grid and the fifth grid on the substrate; and an orthogonal projection of a blue pixel opening on the substrate is located in an orthogonal projection of any of the second grid, the third grid, the fourth grid and the fifth grid on the substrate.

15. (canceled)

16. The display panel according to claim 12, wherein the display panel has a display area, the display area includes a main display region and a photosensitive region, and the first photosensitive openings and the second photosensitive openings are located in the photosensitive region;
in the main display region, the plurality of touch lines are arranged crosswise to constitute a second mesh structure; the second mesh structure includes a plurality of sixth grids, the plurality of sixth grids are arranged in multiple rows and multiple columns, each row includes multiple sixth grids arranged in a second direction, and each column includes multiple sixth grids arranged in a first direction, wherein
sixth grids of two adjacent rows are staggered, and a sixth grid is provided with a first pixel opening therein.

17. The display panel according to claim 16, wherein the sixth grid is substantially in a rhombic shape.

18. The display panel according to claim 1, further comprising:
an encapsulation layer disposed between the black matrix and the substrate, wherein the encapsulation layer includes a plurality of encapsulation sub-films that are stacked, and any two adjacent encapsulation sub-films have different refractive indexes; and/or
a color film disposed on a side of the black matrix away from the substrate, wherein the color film includes a plurality of filter patterns; the plurality of filter patterns and the plurality of second photosensitive openings are staggered, and the orthogonal projection of the second pixel opening on the substrate is located within an orthographic projection of a filter pattern on the substrate.

19. (canceled)

20. The display panel according to claim 1, wherein an orthogonal projection of a first pixel opening on the substrate is located within the orthogonal projection of the second pixel opening on the substrate.

21. A method for manufacturing a display panel, comprising:
forming a pixel defining layer on a substrate, wherein the pixel defining layer is provided therein with a plurality of first pixel openings and a plurality of first photosensitive openings;
forming a first electrode layer on a side of the pixel defining layer away from the substrate; and
forming a black matrix on a side of the first electrode layer away from the substrate, wherein the black matrix is provided therein with a plurality of second pixel openings and a plurality of second photosensitive openings; an orthogonal projection of at least one first pixel opening on the substrate is located within an orthogonal projection of a second pixel opening on the substrate; and an orthogonal projection of at least one second photosensitive opening on the substrate is located within an orthogonal projection of a first photosensitive opening on the substrate.

22. A display apparatus, comprising:
the display panel according to claim 1, the display panel including a light-exit side and a non-light-exit side that are opposite; and
a photosensitive device disposed on the non-light-exit side of the display panel.
